(19) United States
(12) Patent Application Publication
(10) Pub. No.: US 2005/0137814 A1
(43) Pub. Date: Jun. 23, 2005

(54) Method of measuring noise figure using arbitrary waveforms

(76) Inventors: Joseph Kelly, Bridgewater, NJ (US); Miklos T. Kara, Santa Rosa, CA (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/741,895

(22) Filed: Dec. 19, 2003

(51) Int. Cl. G01R 29/26

(52) U.S. Cl. 702/69

(57) ABSTRACT

Noise figure of a device under test (“DUT”) is measured using a programmable RF source and a receiver, such as a spectrum analyzer. The programmable RF source is operated to produce pseudonoise, such as white Gaussian noise (“WGN”), as the hot noise source. Turning the programmable RF source off provides a good termination to the DUT, which is used as a cold noise source. Alternatively, The pseudonoise produced by the programmable RF source is more predictable in amplitude and frequency hopping than true noise, resulting in faster calibration and measurement.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO MICROFICHE APPENDIX

Not applicable.

### FIELD OF THE INVENTION

The invention relates generally to measuring electronic noise, and more particularly to noise figure measurements in high-frequency devices.

### BACKGROUND OF THE INVENTION

Noise figure is an important characteristic of electronic receivers, amplifiers, and other devices. For example, the weakest signal a receiver can detect and resolve depends on how sensitive the receiver is. Sensitivity is often limited by the “noise floor” of the receiver. The noise floor is basically the noise power in the frequency band of interest with no input signal. Input signals must extend sufficiently above the noise floor to be accurately measured.

Noise factor is a figure of merit that has been established to quantify noise. The definition of noise factor is shown in Equation (1):

$$F = \frac{{S}_{i} / {N}_{i}}{{S}_{o} / {N}_{o}} {\vert}_{T = {T}_{0} = 290 K} \qquad Eq . ( 1 )$$

Equation (1) states that noise factor F is the ratio of input signal-to-noise ratio Sᵢ/Nᵢ to output signal-to-noise ratio Sₒ/Nₒ at T=T₀, which is commonly accepted to be 290 K. In other words, noise figure is the degradation of the signal-to-noise ratio at T₀ due to the noise added by the device. However, the magnitude of noise degradation is difficult to measure directly because a noiseless or low-noise device would have the same noise floor at its input and output. A physical device always has an increased noise floor at its output.

The noise factor F is often used to calculate the noise figure NF of a device, which is defined in Equation (2):
NF=10 log(F). Eq. (2)
Noise figure is simply noise factor in units of decibels, and is the more commonly used term in practice. A hypothetical device that added no noise would have a noise factor, F=1, and a noise figure, NF=0 dB. Noise figure measurements involve the characterization of low-level signals, and can be difficult to accurately measure, particularly in a production environment because the noise of the equipment performing the measurement must be significantly lower than the noise of the device being measured.

Noise figure is often categorized as a precision measurement, with an understanding of the device, equipment, and ambient parameters. There are often difficulties in setting up noise figure measurements in a production testing environment. One approach to measuring noise figure in a device under test (“DUT”) places an active noise source, such as an avalanche diode, on a load board. A noise source is a one-port device that provides a known amount of noise to a DUT so that the noise figure can be calculated. In its on, or hot, state the avalanche breakdown mechanism of the diode produces significantly more noise power than when the avalanche diode is in its off, or cold, state. A receiver is used to measure the noise from the avalanche diode in its on and off states, and this data is used to calibrate the test system. Then, the DUT is placed in the signal path from the noise source and the receiver, and the output from the DUT is measured as the diode switches between its on and off states.

Load boards are used in production test systems to provide an interface between the test system and the DUT, and typically provide power to the DUT, as well as providing high-frequency switching paths to various ports of the DUT. The DUT is connected to the load board, which is connected to the test system. The test system generally includes several automatic test instruments, and controls switching of the input and output paths to and from the DUT. It is generally desirable to have as few active components (e.g. transistors and diodes) on the load board as possible because active parts are more susceptible to failure and can generate unwanted noise. Additionally, correlation of the test results from one test system to the next becomes more difficult because active devices are typically more sensitive to aging and temperature variation. Variations in the noise output can require more frequent calibration of the test system, reducing throughput of tested DUTs.

Another approach uses a noise figure meter, such as a Model 8970B™, available from AGILENT TECHNOLOGIES, INC., in the test system with an external active noise source, such as a Model 346B™, also available from AGILENT TECHNOLOGIES, INC. The noise source is not mounted on the load board, but is part of the test system. The noise source is switched into the signal path of the DUT during the noise figure measurement, and is turned on and off by the noise figure meter during the noise figure measurement. This approach adds another high-frequency signal switching path to and from the DUT, complicating the test fixture, and adds another test instrument (the noise figure meter) to the test system, increasing the cost and complexity of the test system.

It is desirable to measure the noise figure of a device without having to include an active noise source on a load board of the device and without having to include a separate noise figure meter into a test system being used to test the device.

### BRIEF SUMMARY OF THE INVENTION

A method of measuring noise figure uses a programmable radio frequency (“RF”) source, such as an automatic test equipment (“ATE”) signal generator, and a receiver, such as a spectrum analyzer. In some embodiments, the programmable RF source and receiver are included in an automatic test system (rack), and routing of the noise signals is done using RF switches on a load board. The test system is calibrated by placing a through line in the signal path between the programmable RF source and the receiver. A first (cold) noise power is produced by turning off the RF source, for example, and the first noise power is coupled to the receiver through the through line. The test system cold noise power is measured over a selected bandwidth with the receiver. The programmable RF source is then operated to produce an arbitrary waveform output simulating hot noise power over the selected bandwidth and the test system hot noise power is measured over the selected bandwidth with the receiver. It does not matter whether the system cold noise power is measured before or after the system hot noise power.

The through line in the signal path is replaced with a DUT and the cold noise power is coupled to the receiver through the DUT. The receiver measures a total cold noise power over the selected bandwidth. Then the programmable RF source is operated to produce the arbitrary waveform output simulating hot noise power over the selected bandwidth, which is coupled to the receiver through the DUT. The receiver measures the total hot noise power over the selected bandwidth. A noise figure of the DUT is calculated using the system hot and cold noise powers, the total hot and cold noise powers, and the selected bandwidth. It does not matter whether the total cold noise power is measured before or after the total hot noise power, or whether the system noise power(s) is measured before or after the total noise power(s). In an alternative embodiment, the cold noise power is also an arbitrary waveform output produced by the programmable RF source.

In further embodiments, the total hot and cold noise powers are measured multiple times and averaged. In particular embodiments, more cold noise power measurements are taken than hot noise power measurements.

### BRIEF DESCRIPTION OF THE DRAWINGS

FIG. 1A is a diagram of a test system according to an embodiment of the invention.

FIG. 1B shows a noise power waveform from the RF signal generator in an embodiment where the RF source is turned on and off.

FIG. 1C shows an output waveform from the RF signal generator in an embodiment where the RF source is left on and the arbitrary waveform alternates between a hot noise portion and a cold noise portion.

FIG. 1D is a diagram of the test system of FIG. 1A configured to perform a noise measurement calibration.

FIG. 2 is a flow chart of a method of measuring noise figure according to another embodiment of the invention.

### DETAILED DESCRIPTION OF THE EMBODIMENTS

I. Introduction

A direct correlation exists between receiver sensitivity and noise figure. In other words, a reduction of 1 dB in noise figure equals a 1 dB improvement of receiver sensitivity gain, and an increase of 1 dB in the noise figure equals a 1 dB degradation of sensitivity gain. Thus noise figure is a critical parameter of devices used in systems with low-power signals, such as cellular communications, satellite communications, wireless local-area networks (“LANs”) and wireless personal-area networks (“PANs”). As demand for such wireless components increases, the need to be able to rapidly and accurately test noise figure in a production environment becomes greater. Consistency between test systems is also important, as is the reliability of the test system and fixturing, such as the load boards used to provide an interface between the test system and the DUTs.

Automatic test systems typically have many automatic test instruments in a rack, with various cabling going to and from the load board and/or DUT. Some test systems are dedicated to testing only one type of DUT, but other test systems are used to test several types of DUTs. Generally, each type of DUT is tested with a specific type of load board. Test systems designed for testing LNAs, power amplifiers, and receivers for use in wireless communication devices typically have a radio-frequency (“RF”) signal generator for providing selected signals to the DUT, and a receiver for measuring signals from the DUT. Some RF signal generators can provide the ability to play back user-defined arbitrary waveforms. Additionally, some have the ability to provide a white Gaussian noise (“WGN”) signal at RF frequencies. Rather than using a noise source, embodiments of the invention use a WGN signal or an arbitrary waveform to measure the noise figure of a DUT.

II. Exemplary Test Systems

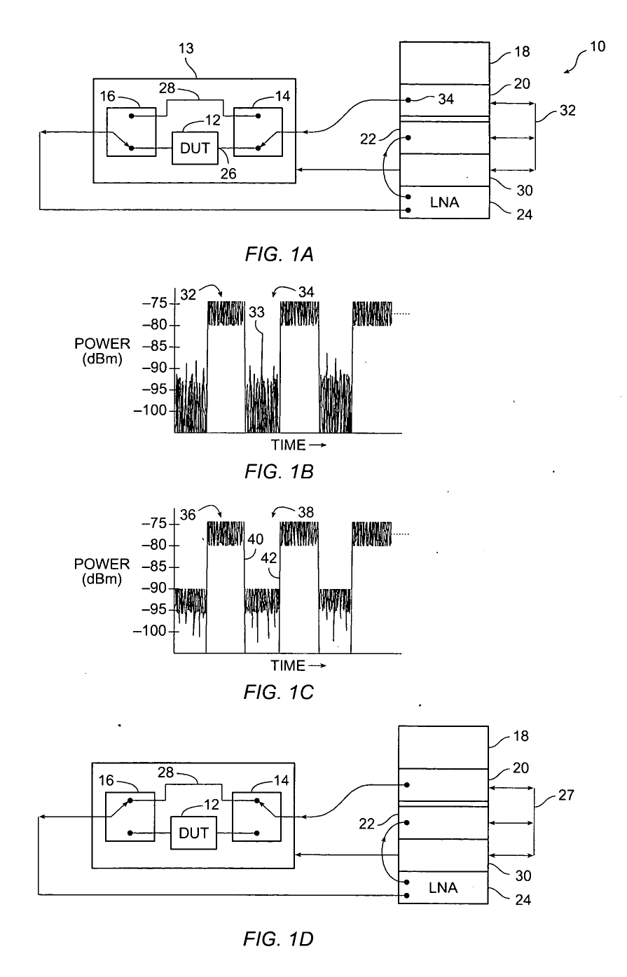

FIG. 1A is a diagram of a test system 10 according to an embodiment of the invention. A DUT 12 is mounted in a load board 13 that provides power and ground return paths to the DUT 12, and includes RF switches 14, 16. A test system rack 18 includes a RF source (e.g. RF signal generator) 20, a receiver 22, and an optional LNA 24. The programmable RF source 20 is coupled to an input 26 of the DUT 12 through the RF switch 14. The programmable RF source 20 is programmable to provide a selected waveform to simulate noise in the on state, and provides a good 50 ohm termination to the input 26 of the DUT 12 when the programmable RF source 20 is in the off state.

Alternatively, the RF source 20 provides a waveform with a first input level of pseudonoise to the DUT to simulate noise in the on state for a first period, and a second (lower) input level of pseudonoise to the DUT to simulate noise in the off state for a second period, rather than turning the RF source off. In other words, the waveform has a high (hot) noise power portion and a low (cold) noise power portion. The receiver 22 is operated to distinguish the on and off states, and to take the appropriate measurements.

FIG. 1B shows a noise power waveform from the RF signal generator in an embodiment where the RF source is turned on and off. The RF source provides an arbitrary waveform that provides “hot” noise 32 when the RF source is turned on, and a 50 ohm termination that provides “cold” noise 34 when the RF source is turned off. A similar noise power waveform would be obtained by leaving the RF source turned on and switching the input of the DUT between the RF source and a termination. Leaving the RF source in an on state is believed to provide more repeatable noise figure measurements, and improve test time in some embodiments, compared to turning the RF source on and off. In some embodiments, the receiver is synchronized with the RF source so that the receiver always measures the same portion of the arbitrary noise waveform. This provides more consistent noise powers and more repeatability in the noise measurements.

The arbitrary waveform, and hence the hot noise, is limited in amplitude, i.e. within an amplitude envelope of −75 dBm to −80 dBm in this example, according to the output power levels selected by the user in generating the arbitrary waveform. The average hot noise power is about −77.5 dBm, and the average cold noise power is about −100 dBm. These values are merely exemplary. The cold noise 34 varies greatly in amplitude, and can range from no power to infinite power, and typically ranges over tens of dBs. Some cold noise power spikes 33 can approach the power level of the average hot noise power. If an avalanche diode is used for the hot noise source, the hot noise power also varies over tens of dBs, and many noise measurements are usually averaged to obtain the hot noise power data used to calculate noise figure.

FIG. 1C shows an output waveform from the RF signal generator in an embodiment where the RF source is left on and the arbitrary waveform alternates between a hot noise portion 36 and a cold noise portion 38. The arbitrary waveform is limited in amplitude over both the hot noise portion 36 and the cold noise portion 38. Limiting the amplitude of the arbitrary waveform provides more consistent noise measurements, which provides enhanced repeatability of measured NF with less averaging of the noise readings.

The average hot noise power is about −77.5 dBm, and the average cold noise power is about −92.5 dBm, or about 15 dB lower; however, these values are merely exemplary. The average cold noise power is higher than the average cold noise power from a termination. A higher noise power is easier to calibrate, but if the difference between the hot and cold noise powers is low the NF of the DUT may be difficult to measure, especially if the DUT does not contribute much noise. Using an arbitrary waveform as the cold noise source allows the RF source to be left in an on state, and also allows the receiver to be synchronized to the RF source when measuring the cold noise power, as discussed above in relation to FIG. 1B.

The receiver is synchronized to the RF source in a closed fashion by providing the appropriate trigger from the controller to the receiver so that the receiver measures the hot and cold noise powers at specific times after the noise source switches states. If the noise source is an arbitrary waveform, the receiver can measure the same portion of the arbitrary waveform several times, further reducing the need to average measurements because the input noise power is more consistent. Alternatively, the receiver is synchronized to the RF source in an open fashion by having the receiver detect when the noise power changes states, for example by detecting the edges 40, 42 of the arbitrary waveform and measuring over the selected noise bandwidth after a selected, fixed time. The arbitrary waveform repeats the same hot and cold pseudonoise output and the receiver automatically measures and averages a selected number of times. This approach avoids having to address the RF source during the noise figure measurement, other than to initiate the arbitrary waveform at the beginning, and to turn the arbitrary waveform off when the receiver has made a sufficient number of hot/cold measurements.

The system is calibrated for noise figure measurements by switching a through line 28 in the signal path (see FIG. 1D) and measuring the hot and cold noise of the system with the receiver 22. It is assumed that the through line contributes essentially zero noise to the system. Alternatively, the RF switches are omitted and a through line is inserted in place of the DUT 12. In one instance, the receiver was an HP E6404. Generally, a receiver that is capable of measuring the intended signal power levels within the intended bandwidth(s) is suitable. In some embodiments, the intended bandwidth is between about 1 MHz and about 4 MHz.

In one embodiment, a programmable RF source, such as a Model 4438™ signal generator, option 002, available from AGILENT TECHNOLOGIES, INC., is programmed to generate a WGN noise signal over the frequency range of interest. This RF source provides signals from 250 kHz to 6 GHz with 14-bit resolution at 100 MHz maximum sample rate in each of its dual arbitrary waveform generators. The programmable RF source 18 has an output attenuator (not shown) that is used to set the output level of the source, and its use is transparent to the user. The attenuator is automatically set according to the output power level requested by the user. Output power levels in the range of −75 dBm to −85 dBm over a 40 MHz-wide noise bandwidth provided a noise power similar to that of a conventional noise diode source having an excess noise ratio (“ENR”) of 8 to 23 dB. Generally, one tries to use a noise source with an ENR (in dB) that is close to the sum of the NF of the DUT and the gain of the DUT, both also in dB.

The programmable RF source 20 is programmable from its front panel to produce a noise waveform, or alternatively is controlled by a computer 30, also known as the system controller, according to a computer program. The computer program (also known as computer files) is usually created on another computer (not shown) and transferred from that computer to the system controller 30 on a disk or over a link. The system controller 30 controls automatic test equipment in the test system 10 over a bus 32, and typically also controls the load board 13.

In a specific embodiment, MATLAB™ 6.1, available from THE MATHWORKS, INC., of Natick, Mass., was used to create a program for controlling the programmable RF source 16 to create an arbitrary noise waveform. The randn( ) function was used to create in-phase and quadrature-phase waveforms. This particular algorithm used a sampling rate of 100 Ms/s then applied a sharp cutoff 20 MHz lowpass, (1023-tap finite impulse response (“FIR”) filter with a Kaiser window and beta=13.3). Other methods are alternatively used to produce bandwidth-limited Gaussian noise, including the built-in noise function available with some RF sources.

In general, the arbitrary noise waveform is made up of random complex samples with amplitudes that have a mean Gaussian distribution of zero, the spectrum is zero outside the given bandwidth, and flat within the bandwidth. Such an arbitrary waveform mimics a conventional diode noise source in the selected bandwidth. However, embodiments include selecting the amplitude of the arbitrary waveform to have small variations, relative to a noise diode source. Amplitude fluctuations of a noise diode source at a fixed frequency can vary over several 10's of dBs, and calibration of conventional diode noise sources typically is done averaging many readings.

Using an arbitrary noise waveform with selected amplitude variation provides pseudonoise in which the noise power does not vary much over the bandwidth of interest, so less averaging is required to accurately calibrate the noise power output. The noise power is not constant over time, but the short-term power is relatively constant. The arbitrary noise waveform is random in the sense that it is uncorrelated with itself during the measurement period, and it is uncorrelated with any other noise in the DUT or test system, yet sufficiently constant for a relatively quick power measurement.

The bandwidth of the noise is chosen to be sufficiently wide to allow the flat portion of the receiver bandwidth to used for the noise measurement, i.e. the noise bandwidth is wider than the receiver bandwidth. The receiver cannot distinguish this bandwidth-limited noise from the noise from a conventional noise diode source or an infinitely wide noise source. The total noise power from the RF source is reduced because the waveform occurs over a relatively finite bandwidth.

After filtering, the initial samples are discarded and any DC offset present is removed. The number of discarded samples depends on the time response of the filter being used. An FIR filter has a finite, definite, response, and the samples to discard are easy to identify, and depend upon its length in samples (number of taps). If an infinite impulse response filter is used, the boundary between the initial samples is not as well defined, and samples are generally discarded until the filter response has settled, which is open to variation. The result is scaled to fit the range of the programmable RF source. For example, if the RF source uses 14-bit integers to describe samples, the samples are scaled to fit into [−8192, +8191].

The programmable RF source 20 receives the files from the system controller 30 or other computer (not shown), stores them in memory (not shown), then uses the files to create a modulating signal, which is subsequently up-converted to provide a modulated noise signal at RF frequencies at the output 34 of the programmable RF source 20. The automatic level control (“ALC”) built into this RF source keeps the noise power level at a selectable value.

An advantage of the test systems shown in FIG. 1A is that many ATE test systems already contain RF sources that have the capability to produce arbitrary waveforms. Using the programmable RF source as a pseudonoise source allows these test systems to make noise figure measurements without a dedicated noise figure meter in the test system rack 18. Furthermore, the test signal from the programmable RF source 20 is typically calibrated with high accuracy to the DUT input 26. In other words, all of the hardware needed to perform noise figure measurements is already built into many existing ATE platforms (test systems), and much of the calibration for noise figure measurements is already done for other tests performed by the test system 10.

A significant advantage for testing noise figure in a production environment arises because the arbitrary waveform noise produced by the programmable RF source 20 is pseudonoise, which is different from the noise obtained from avalanche diodes used in traditional noise figure measurements. An avalanche diode produces very wideband noise, which results in a lot of the noise power produced by the avalanche diode going to waste if one only needs noise power within the measurement bandwidth.

To achieve a noise level within the measurement band, the total RF power delivered by the RF source is less compared to the noise power produced by an avalanche diode. In other words, there is essentially no extra noise in the spectrum, the noise power is only provided in the measurement bandwidth. Tuning the RF source to provide noise at different frequencies of interest does not appreciably slow test time because the receiver has to be tuned to the new frequency(s) as well.

III. Exemplary Methods

A noise source is typically characterized by its ENR. The ENR is a term used to describe the output of a noise source when it is used as an input stimulus to a circuit. The ENR of an arbitrary waveform generated by the programmable RF source has a lower power limit; therefore, using a programmable RF source for measuring extremely low noise figures may be difficult. However, devices with such low noise figures are not common in consumer devices. The definition of ENR is given in Equation (3):

$$ENR = \frac{{T}_{h} - {T}_{c}}{{T}_{0}} \qquad Eq . ( 3 )$$

where Tₕ is the equivalent noise temperature of the noise source in the on, or hot state (in degrees Kelvin), T_{c}, is the equivalent noise temperature of the noise source in the cold state, and T₀ is the reference temperature (assumed to be the standard room temperature of 290° K). Most often, in production testing of DUTs, T_{c}, is assumed to be T₀, making:

$$ENR = \frac{{T}_{h}}{{T}_{0}} - 1. \qquad Eq . ( 4 )$$

The above definitions provide ENR in linear units. It is more common to use logarithmic values when using ATE test equipment at RF frequencies, which are calculated as follows:
ENR|_{dB=}10*log(ENR). Eq. (5)

It is generally desirable for a noise source to have an ENR greater than about 10 dB so that there is sufficient difference in the output power measured by the receiver between the on and off states. The ENR for typical commercial diode noise sources such as the Model 346B™ is about 15 dB. In other words, the noise in the on state is 15 dB higher than the noise in the off state.

In embodiments of the invention, a computer-readable file is created that produces an arbitrary waveform when executed (read) by the programmable RF source. An ENR is calculated during the creation of the arbitrary waveform file based on the number of points in the file and also on the sample rate of playback at the programmable RF source. Unlike avalanche diodes, the ENR produced by the arbitrary waveform generator for the programmable RF source is variable, which makes it suitable for multiple types of devices having either very low or very high noise figures.

A common technique for measuring noise that uses two different noise sources (noise levels) is the Y-factor technique. A “cold” noise source corresponds to a termination (e.g. a 50 ohm termination) at a cold temperature T_{c}, which is typically 290 K temperature T₀, and the “hot” noise source corresponds to the termination at a hot temperature Tₕ. In its on state, an avalanche diode emits a noise power corresponding to the noise that would be generated by the 50 ohm termination at Tₕ. The Y-factor is a ratio of “hot” to “cold” noise power (Watts) and is defined as

$$Y = \frac{{N}_{h}}{{N}_{c}} . \qquad Eq . ( 6 )$$

If the noise source is at room temperature and the cold state is that of the noise source simply turned off then T_{c}=T₀ and (6) becomes

$$Y = \frac{{N}_{h}}{{N}_{0}} . \qquad Eq . ( 7 )$$

Traditionally, a single avalanche diode acts as both the hot and cold noise source. In the on state the avalanche diode is the hot noise source, and in the off state it is the cold noise source. In embodiments of the present invention, the programmable RF source is turned on or off. The “hot” noise source is the modulated arbitrary waveform coming from the programmable RF source at a power level greater than the noise floor of the measurement receiver. The “cold” noise source is the programmable RF source in the off state, which provides a good 50 ohm termination to the DUT. Alternatively, the programmable RF source is left on and provides an arbitrary waveform that alternates between a hot noise portion and a cold noise portion (see FIG. 1C, ref. nums. 36, 38).

The match presented to the input of any device affects its noise figure. Commercial noise figure meters, such as the AGILENT Model 8970™, are typically well-matched to 50 ohms. Although 50 ohms may not be the optimal impedance match to measure noise figure for the DUT, it provides a repeatable measurement. Impedance mismatch between the system and the DUT can occur at both the input and output to the DUT. Measuring noise circles of DUTs, which show the dependency of NF on impedance matching, are slow measurements requiring special test instrumentation, and are rarely done. Measuring DUTs in a 50 ohm in a 50 ohm environment produces a useable and repeatable figure of merit regarding noise performance.

An LNA, which has a low noise figure and high gain, is optionally added between the DUT and the receiver to improve the signal-to-noise ratio of the noise power measured by the receiver. The LNA is added to the load board, or alternatively to the test system rack to keep the number of active components on the load board low. From the Friis Equation:

$${F}_{LNA + tester} = {F}_{LNA} + \frac{{F}_{tester} - 1}{{G}_{LNA}} \qquad Eq . ( 8 )$$

it can be seen that adding an LNA, with a low noise figure and high gain, will act to reduce the overall receiver noise as the first stage of the receiver, which reduces the overall noise figure F_{LNA+tester}.

Rearranging Equation (8) as:

$${F}_{LNA} = {F}_{LNA + tester} - \frac{{F}_{tester} - 1}{{G}_{tester}} \qquad Eq . ( 9 )$$

the noise figure of the LNA is calculated from four different power measurements:
1. Measuring the hot noise power with a through line in the signal path
2. Measuring the cold noise power with a through line in the signal path
3. Measuring the hot noise power with the DUT in the signal path
4. Measuring the cold noise power with the DUT in the signal path

Measurements 1 and 2 calibrate the test system, where the noise figure of the receiver (F_{LNA+tester}) is determined from hot and cold noise power measurements without the DUT present. This may be accomplished through the use of RF switches to bypass the DUT (see FIG. 1D), or by placing a through line in the signal path in place of the DUT. Noise measurements are specified for a characteristic impedance because the NF depends on the mismatch between the DUT and the system it is tested or used in. The cold noise power is often the noise coming from a termination having the characteristic impedance of the test system at room temperature, and the hot noise power corresponds to the noise power that would emanate from the termination at an elevated power.

First, the programmable RF source is turned on to provide pseudonoise over a selected bandwidth and a power measurement, Pₕ₂, is made. Then the programmable RF source is turned off, which provides a relatively good 50 ohm termination to the input port of the DUT, and another power measurement, P_{c2}, is made. Alternatively, the cold noise measurement is made first, and then the programmable RF source is turned on and the hot noise measurement is made. In yet another embodiment, the RF source is left on and the arbitrary waveform output alternates between a hot noise power level and a cold noise power level. From these two values, the Y-Factor, Y₂, of the measurement equipment is determined as:

$${Y}_{2} = \frac{{P}_{h 2}}{{P}_{c 2}} . \qquad Eq . ( 10 )$$

Measurements 3 and 4 are hot and cold noise power measurements with the DUT switched into the measurement path. From these two values, the Y-Factor, Y₁₂, of the overall setup (DUT and measurement receiver) is determined as:

$${Y}_{12} = \frac{{P}_{h 12}}{{P}_{c 12}} . \qquad Eq . ( 11 )$$

Additionally, a third power ratio is defined as:

$$X = \frac{{P}_{h 12}}{{P}_{h 2}} . \qquad Eq . ( 12 )$$

Using these ratios, the noise factor of the DUT, F₁, is calculated as:

$${F}_{1} = 1 + \frac{{P}_{hot} ( 1 - \frac{{Y}_{12}}{{XY}_{2}} ) - {P}_{cold} ( {Y}_{12} - \frac{{Y}_{12}}{X} )}{{kT}_{0} B ( {Y}_{12} - 1 )} \qquad Eq . ( 13 )$$

where k=1.380658·10⁻²³ J/K (Boltzmann's constant), T₀=290 K (standard temperature for noise measurements), Pₕₒₜ and P_{cold} are the total power in Watts of a white noise source over B Hz bandwidth. The gain of the DUT is calculated as:

$${G}_{1} = X \frac{1 - \frac{1}{{Y}_{12}}}{1 - \frac{1}{{Y}_{2}}} . \qquad Eq . ( 14 )$$

Thus, when measuring a DUT with amplification, the gain may be derived from data taken for the noise figure measurement. Lossy devices are more difficult to measure, but the DUT still has an input and an output, and the output power is still determined by the gain (negative gain, or loss) of the DUT output power and input power.
FIG. 1B is a diagram of the test system 10 of FIG. 1A configured to perform a noise measurement calibration. The RF switches 14, 16 have been switched to couple the pseudonoise signal from the programmable RF source 20 to the through line 28, and from the through line 28 to the LNA 24 and receiver 22 (see steps (1) and (2), above, following Equation (9)).

Referring again to FIG. 1A, the test system 10 is configured to measure the hot and cold noise power of the DUT 12 in the signal path from the programmable RF source 20 to the receiver 22. The RF switches 14, 16 couple a pseudonoise signal from the programmable RF source 20 to the DUT 12, and from the DUT 12 to the LNA 24 and receiver 22 (see steps (3) and (4), above, following Equation (9)).

When measuring the noise figure of DUTs in a production environment, it is important that the measured noise figure is repeatable, fast, and that several DUTs can be measured before the test system needs to be re-calibrated. While other types of noise measurements have been performed using a programmable RF source and a receiver, such as characterizing a DUT according to its noise power ratio, measuring the noise figure of the DUT is desirable because noise figure is a calibrated measurement that can be traced back to National Institute of Standards and Technology (“NIST”) standards. Noise figure measurements performed on a production test system can be correlated with measurements performed on a NIST-traceable system. Noise power ratio, in comparison, does not show the noise added by a DUT, but only the noise power out, and hence may represent a combination of noise added, gain, and saturated output power of the DUT. Noise power ratio is a linearity measurement, and can be thought of as a two-tone or multi-tone measurement. Noise power ratio measurements are used to characterize distortion in a wideband system.

Stability and temperature drift of the noise source and receiver can significantly affect the accuracy and repeatability of noise figure measurements. An RF source can be calibrated on a regular basis using a calibrated power sensor at a relatively high power output level, which speeds calibration. In comparison, an avalanche diode is a calibrated source that is difficult to verify because its output power levels are so low. In one embodiment of the present invention, the noise figure of 50 DUTs was measured before the test system was re-calibrated. It is anticipated that even more DUTs could be measured in other embodiments, particularly if the ambient temperature of the test system is stable between the time the calibration is performed and when the measurements are taken.

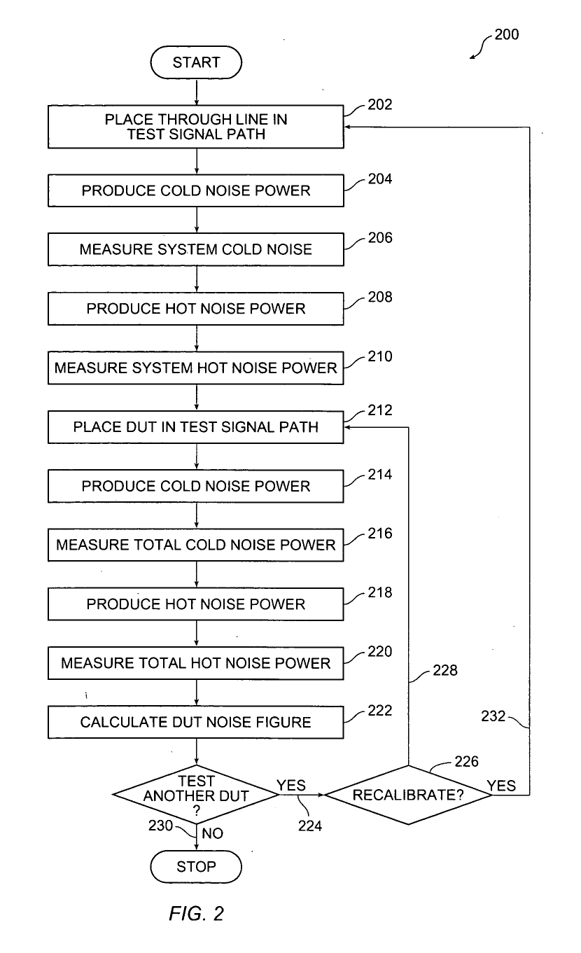

FIG. 2 is a flow chart of a method 200 of measuring noise figure according to an embodiment of the invention. A through line is placed in a test signal path between a programmable RF source and a receiver (step 202) to calibrate the test system. In some embodiments the through line is switched into the test signal path using RF switches on a load board. Noise power at a first (e.g. cold) noise power level is produced (step 204) and is coupled through the through line to the receiver and a test system first noise power is measured by the receiver over a selected bandwidth (step 206). Cold noise power is produced by turning the programmable RF source off, coupling the input of the through line to a 50 ohm termination or other noise source, or by providing a very-low level pseudonoise signal from the programmable RF source, for example. The cold noise of the test system is typically measured many times and averaged. Averaging measured noise power improves the accuracy of, and confidence in, the measured noise power because noise power fluctuates. Fewer averages are typically needed if the cold noise power is provided by the RF source because the noise amplitude is limited, and hence less variation in the noise power occurs.

The programmable RF source is operated to produce an arbitrary waveform output (pseudonoise) simulating hot noise power over a selected test bandwidth (step 208), which is coupled to the receiver through the through line, and a test system hot noise power measurement is made by the receiver over the selected test bandwidth (step 210). The arbitrary waveform output has a relatively constant power envelope over the selected test bandwidth, and has a user-selectable output power level.

The through line in the test signal path is replaced with a DUT (step 212) and the first noise power that was used in step 204 is produced (step 214). The first noise power (e.g. cold noise power) is coupled to the receiver with the DUT in the test signal path and a total cold noise power of the test system and DUT is measured by the receiver over the selected bandwidth (step 216). The arbitrary waveform output (e.g. hot noise power) used in step 208 is produced by the programmable RF source (step 218), which is coupled to the receiver with the DUT in the test signal path, and a total hot noise power of the test system and DUT is measured by the receiver over the selected bandwidth (step 220). A DUT noise figure is calculated (step 222) from the test system cold noise power, the test system hot noise power, the total cold noise power, and the total hot noise power.

If another DUT is to be tested (branch 224), a determination of whether the test system needs to be recalibrated is optionally made (step 226). The recalibration criterion can be based on the number of units tested since the last calibration, or the elapsed time since calibration, for example. In some embodiments it may be desirable to measure the system noise power using a through line each time a DUT is tested. If recalibration is not required (branch 228), steps 212-222 are repeated until no more DUTs are to be measured (branch 230). If calibration is required (step 232), the through line is placed in the signal path and steps 202-210 are repeated before the next DUT is placed in the signal path. An amplifier, such as an LNA, is optionally placed between the through line/DUT and the receiver. The amplifier amplifies the system and total cold and hot noise, and the noise contribution of the LNA is accounted for in the system noise measurements.

IV. Experimental Results

Measurements of an LNA having a noise figure of about 1.5 dB were taken to determine the repeatability of the noise figure measured by a test system in accordance with FIGS. 1A and 1D. The RF source was turned off to provide a 50 ohm termination as the cold noise source. The number of averages taken with a hot noise power input and with a cold noise power input was varied to evaluate the sensitivity of measurement repeatability to the number of averages taken. Each type of noise figure measurement (e.g. 2/2, 2/4, etc.) was repeated 100 times to obtain the standard deviation. The noise figure was measured in dB, so the “standard deviation” is not the same as a linear standard deviation, but is provided as an indication of relative repeatability between measurement conditions. The test results are shown in Table 1:

TABLE 1

| No. Avgs. | Standard |
|---|---|
| (hot/cold) | deviation |
| 2/2 | 0.19 |
| 2/4 | 0.11 |
| 2/8 | 0.10 |
| 2/16 | 0.08 |
| 2/32 | 0.06 |
| 4/4 | 0.11 |
| 4/8 | 0.09 |
| 4/16 | 0.07 |
| 4/32 | 0.06 |
| 8/8 | 0.11 |
| 8/16 | 0.09 |
| 8/32 | 0.07 |
| 16/16 | 0.06 |
| 16/32 | 0.05 |
| 32/32 | 0.05 |

Table 1 shows that the standard deviation of the noise figure is more dependent on the number of cold noise power averages and less dependent on the number of hot noise power averages. Considering the four cases that have only two hot averages, the standard deviation values ranged from 0.19 dB to 0.08 dB. Considering the four cases where sixteen cold averages were taken, the standard deviation values ranged from 0.08 (where two hot noise power averages were taken) to 0.06 (where sixteen hot noise power averages were taken). Thus the range of standard deviation appears to be more dependent on the number of cold noise power averages that are taken than on the number of hot noise power averages that are taken. This demonstrates that, because of lower peak-to-peak variations from the arbitrary waveform generated noise source, the hot noise powers can be obtained with a small number of measurement averages.

Table 1 also shows that a variety of measurement sequences can be used to obtain a given standard deviation. For example, if a customer requires a measurement-to-measurement standard deviation of 0.11, this is obtainable using two hot/four cold, four hot/four cold, or eight hot/eight cold measurements. Making the least number of measurements, i.e. two hot/four cold, is desirable to minimize test time. The acceptable standard deviation depends on the device specifications and performance. However, Table 1 shows that very repeatable noise figure measurements can be made with a small number of measurement averages, which reduces test time. Similarly, the stability, predictability, and/or selectable output level of the programmable RF source reduces calibration time, reducing the average overall test time per DUT. In a particular instance, a noise figure measurement was made on an LNA having a nominal noise figure of 1.5 dB over a 2 MHz measurement bandwidth (40 MHz noise signal bandwidth) in less than 100 milliseconds.

While the preferred embodiments of the present invention have been illustrated in detail, it should be apparent that modifications and adaptations to these embodiments might occur to one skilled in the art without departing from the scope of the present invention. Therefore, the scope of the present invention is set forth in the following claims.

1. A method of measuring noise figure comprising:
placing a through line between a source and a receiver;
producing first noise power;
measuring a first measured noise power over a selected bandwidth with the receiver;
programming the source to produce an arbitrary waveform simulating hot noise power over the selected bandwidth;
measuring a second measured noise power over the selected bandwidth with the receiver;
placing a device under test (“DUT”) between the source and the receiver;
producing the first noise power;
measuring a third measured noise power with the receiver;
programming the source to produce the arbitrary waveform;
measuring a fourth measured noise power over the selected bandwidth with the receiver; and
calculating a noise figure of the DUT.

2. The method of claim 1 wherein the step of placing a through line comprises using RF switches to switch the DUT out of a signal path and the through line into the signal path.

3. The method of claim 1 wherein the arbitrary waveform comprises a bandwidth-limited white Gaussian noise waveform.

4. The method of claim 1 wherein the step of measuring the third measured noise power with the receiver comprises measuring the third measured noise power N times to obtain N third measured noise powers, where N is an integer greater than one, and averaging the N third measured noise powers to obtain an average third measured noise power used to calculate the noise figure of the DUT.

5. The method of claim 1 wherein the step of measuring the fourth measured noise power comprises measuring the fourth measured noise power M times to obtain M fourth measured noise powers, where M is an integer greater than one, and averaging the M fourth measured noise powers to obtain an average fourth measured noise power used to calculate the noise figure of the DUT.

6. The method of claim 1 wherein the step of measuring the fourth measured noise power comprises measuring the fourth measured noise power M times to obtain M fourth measured noise powers, where M is an integer greater than one, and averaging the M fourth measured noise powers to obtain an average fourth measured noise power, and wherein the step of measuring the third measured noise power with the receiver comprises measuring the third measured noise power N times to obtain N third measured noise powers, where N is an integer greater than M, and averaging the N third measured noise powers to obtain an average third measured noise power, and the noise figure of the DUT is calculated using the average fourth measured noise power and the average third measured noise power.

7. The method of claim 1 wherein the step of producing first noise power comprises turning off the source.

8. The method of claim 1 wherein the step of producing the first noise power comprises programming the source to produce a second arbitrary waveform simulating cold noise power over the selected bandwidth.

9. The method of claim 1 wherein the step of producing the first noise power comprises coupling a termination to the through line.

10. The method of claim 1 wherein the source is in an on state between the step of measuring the second measured noise power and the step of measuring the fourth measured noise power.

11. The method of claim 1 further comprising steps, prior to the step of measuring the third measured noise power, of
identifying a cold noise portion of the arbitrary waveform with the receiver; and, prior to the step of measuring the fourth measured noise power, of
identifying a hot noise portion of the arbitrary waveform with the receiver.

12. The method of claim 1 wherein the receiver is a spectrum analyzer.

13. The method of claim 12 wherein the spectrum analyzer is synchronized to the source to measure a selected portion of the arbitrary waveform.

14. An electronic device measured according to the method of claim 1.

15. A method of measuring noise figure comprising:
placing a through line between a source and an amplifier coupled to a receiver;
producing first noise power;
amplifying the first noise power;
measuring a first measured noise power over a selected bandwidth with the receiver;
programming the source to produce an arbitrary waveform simulating hot noise power over the selected bandwidth;
amplifying the arbitrary waveform;
measuring a second measured noise power over the selected bandwidth with the receiver;
placing a device under test (“DUT”) between the source and the amplifier;
producing the first noise power;
measuring a third measured noise power over the selected bandwidth with the receiver;
programming the source to produce the arbitrary waveform simulating hot noise power over the selected bandwidth;
measuring a fourth measured noise power over the selected bandwidth with the receiver; and
calculating a noise figure of the DUT.
